(19) United States
(12) Patent Application Publication
(10) Pub. No.: US 2003/0179021 A1
(43) Pub. Date: Sep. 25, 2003

(54) Drive control circuit for a junction field-effect transistor

(75) Inventors: Matthias Braun, Florsbachtal (DE); Benno Weis, Hemhofen (DE)

Correspondence Address: HENRY M FEIEREISEN, LLC, 350 FIFTH AVENUE, SUITE 4714, NEW YORK, NY, 10118, US

(73) Assignee: SIEMENS AKTIENGESELLSCHAFT, Muchen (DE)

(21) Appl. No.: 10/392,705

(22) Filed: Mar. 20, 2003

(30) Foreign Application Priority Data
Mar. 22, 2002 (DE) 102 12 869.3

(51) Int. Cl. H03B 1/00

(52) U.S. Cl. 327/108

(57) ABSTRACT

A drive control circuit for a junction field-effect transistor having a gate terminal, a drain terminal and a source terminal, includes a controllable current supply or voltage supply to produce a reverse control current or a reverse control voltage for the gate. The current supply or voltage supply is controlled in such a way that upon a switch-off of the junction field-effect transistor, the absolute magnitude of the reverse control current or the reverse control voltage assumes initially a higher value and then a lower value, whereby the lower value is sufficient for blocking the junction field-effect of the transistor.

### CROSS-REFERENCES TO RELATED APPLICATIONS

This application claims the priority of German Patent Application, Serial No. 102 12 869.3, filed Mar. 22, 2002, pursuant to 35 U.S.C. 119(a)-(d), the disclosure of which is incorporated herein by reference.

### BACKGROUND OF THE INVENTION

The present invention relates, in general, to a drive control circuit for a junction field-effect transistor.

A typical inverter arrangement has junction field-effect transistors (JFETs) which are conducting elements and have been described, for example, by U. Tietze and Ch. Schenk in Halbleiter-Schaltungstechnik [Semiconductor Circuit Technology], 9^{th} Edition 1990, pages 83 to 101. Such junction field-effect transistors with a gate voltage of 0 V are conducting but become inhibiting with negative gate voltages. In the switched on state, the junction field-effect transistor can conduct current in both directions. Thus, it represents a symmetrical electrical component. Further, the junction field-effect transistor possesses a structural pin diode that permits current in backwards direction independent of the gate voltage (source-drain direction). A diode-free inverter can be easily implemented with such a junction field-effect transistor.

FIG. 1 schematically shows such a typical inverter arrangement using two junction field-effect transistors T1 and T2, having drain-source paths connected to each other in series between a positive supply voltage +V and a negative supply voltage −V. More specifically, the drain terminal of the junction field-effect transistor T1 is connected to the positive supply voltage +V, and the source terminal of the junction field-effect transistor T2 is connected to the negative supply voltage −V. The source terminal of the junction field-effect transistor T1 and the drain terminal of the junction field-effect transistor T2 are coupled to one another and connected to a load L whose other terminal is connected to ground potential between the supply voltages +V and −V, or is equal to one of these supply voltages +V or −V.

It is assumed that a current flows freely in the branch composed of the load L and the drain-source path of the junction field-effect transistor T1. The gate-source voltage of the junction field-effect transistor T1 is negative based on a turned-off field-effect transistor of N-conductor-type. The freewheeling current then flows via the internal free-wheel diode of the junction field-effect transistor T1. When the junction field-effect transistor T2 is now turned on, the current commutates from the junction field-effect transistor T1 to the field-effect transistor T2. As a consequence, the junction field-effect transistor T2 reduces its reverse voltage while the junction field-effect transistor T1 increases its reverse voltage. In order to reduce loss as much as possible, higher switching speeds are desired.

FIG. 2 shows the parasitic dynamic replacement elements of a junction field-effect of transistor JFET. Involved here are a parasitic capacitance between drain D and gate G (capacitance Cdg), a parasitic capacitance between gate G and source S (capacitance Cgs) as well as a gate resistor Rg which is connected before the gate and across which an interference voltage Ustör drops, when a voltage Uminus is applied between gate G and source S. As gate G of the junction field-effect transistor JFET is always at a voltage near the source voltage, the drain-source voltage and the drain-gate voltage of the junction field-effect transistor JFET are substantially identical. When in the example shown in FIG. 1, the voltage of the junction field-effect transistor T1 quickly increases, i.e. the drain-source voltage very quickly rises to high values, the drain-gate voltage increases likewise to high values. As a consequence of the inevitable drain-gate capacitance Cdg (Miller capacitance), the rise in voltage forces a current flow out of the gate G of the junction field-effect transistor JFET. This current has to flow across the gate resistance Rg, causing there the voltage drop Ustör which raises the gate voltage in relation to the outside control voltage Uminus. The voltage drop Ustör is hereby proportional to the gate resistance Rg, and to the switching slope dUdg/dt. If this voltage drop becomes large enough so that the gate voltage is increased to the level of the source voltage, the junction field-effect transistor JFET (the junction field-effect transistor T1 in FIG. 1) is activated and develops a short-circuit bridge, since the junction field-effect transistor T2 in FIG. 1 is likewise switched on by definition.

The voltage Uminus is usually selected in such a way that the voltage drop Ustör is not sufficient to raise the gate voltage to a level that the junction field-effect transistor JFET is activated. For this reason, the resistance Rg is also selected as small as possible.

Minimum values for the gate resistance Rg, and the drain-gate capacitance Cdg are technologically predetermined for embodiments of silicon carbide junction field-effect transistors. Both, in particular however the gate-resistor Rg, are dimensioned that at an acceptable switching speed (for example 1000 V/μs) the voltage drop Ustör exceeds the maximum blocking capability of the gate-source path. If the control voltage Uminus were to fall so far that the voltage drop Ustör does not lead to a faulty switching, then the gate-source path of the junction field-effect transistor would normally be thermally destroyed, because the voltage drop Ustör appears only for a very short time and during the remaining time a very high negative gate voltage is applied at the junction field-effect transistor. This would lead to an inadmissibly high gate current. Therefore, conventional measures are not applicable in silicon carbide field-effect transistors.

Therefore, there appears to remain as the only option to reduce the switching speed of the junction field-effect transistor in order to decrease the voltage drop Ustör. This, however, is accompanied by a substantial and unacceptable increase in switching losses.

It would therefore be desirable and advantageous to provide an improved drive control circuit for a junction field-effect transistor to obviate prior art shortcomings.

### SUMMARY OF THE INVENTION

According to one aspect of the present invention, a drive control circuit for a junction field-effect transistor of a type including a gate terminal, a drain terminal and a source terminal, includes a controllable current supply or voltage supply to produce a reverse control current or a reverse control voltage, respectively, for the gate, whereby the current supply or voltage supply is controlled in such a way that, when the junction field-effect of the transistor is turned off, the absolute magnitude of the reverse control current or the reverse control voltage assumes initially a higher value and then a lower value, whereby the lower value is sufficient for blocking the junction field-effect of the transistor.

To ensure clarity, it is necessary to establish the definition of important terms and expressions that will be used throughout this disclosure. The term “current transfer” relates to a situation, when a transistor turns off and current is transmitted to another transistor, i.e. current flows across the gate resistor from the gate of the transistor that turns off.

In accordance with the present invention, the gate-source voltage of the junction field-effect transistor is kept within a range that ensures a safe cutoff, without subjecting the gate-source distance to excessive voltage. Thus, the control voltage Uminus is lowered dynamically during the switching procedure. For example, if the static gate voltage is adjusted to −17 V, the static gate voltage could be adjusted through current transfer, for example, to −27 V. In this way, the voltage drop Ustör can prevent the junction field-effect transistor T1 of FIG. 1 from turning on. As the decrease of the gate voltage is executed only during the current transfer, additional heating as a result of the increased gate current is negligible. However, the transistor, which is turning off, is prevented from turning on again, and therefore the presence of a shunt current can be avoided.

As an alternative, it is possible to raise in addition to the control voltage Uminus also the gate current, especially the gate leakage current, in absolute terms. In normal operation, a certain desired leakage current is hereby adjusted. A higher leakage current that incorporates the interference current through the Miller capacitance is made available during current transfer. The total current can thus be drawn from the Miller capacitance, and an increase in the gate voltage can be prevented.

According to another feature of the present invention, there may be provided a timing control for the current supply or voltage supply for increasing the reverse control current or reverse control voltage from a lower value to a higher value for a certain period of time when the presence of an edge of a switching signal initiates a switch-off of the junction field-effect transistor. Suitably, the higher value of the reverse control current or reverse control voltage is set to approximately the maximally allowed value for the gate current or gate voltage.

According to another feature of the present invention, the junction field-effect transistor may be a silicon-carbide field-effect transistor.

Thus, a drive control circuit according to the invention includes a switch between two different values of the reverse control current or the reverse control voltage. The rise of the drive control is, preferably, employed when an internal free-wheel diode (parasitic diode of a junction field-effect transistor) was conductive and the respectively other junction field-effect transistor switches on in the same bridge arm.

Since it is difficult to transmit the switch-on time instance via a possibly existent voltage separation, the command for the desired value switchover is suitably linked with the switch-off command for the junction field-effect transistor. The rise of the reverse control current or the reverse control voltage should last at least as long as the change in blocking time because during this time the unwanted behavior described above is encountered. After a possible further safety period, it can again be switched over to the steady state, i.e. the smaller desired value.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 is a schematic circuit diagram of an inverter arrangement;

FIG. 2 is an equivalent circuit diagram of a junction field-effect transistor;

FIG. 3a is a circuit diagram of a first embodiment of a drive control circuit according to the present invention;

FIG. 3b is a graphical illustration of input signals and output signals of a monostable multivibrator;

FIG. 4 is a circuit diagram of a second embodiment of a drive control circuit according to the present invention; and

FIG. 5 is a circuit diagram of a third embodiment of a drive control circuit according to the present invention.

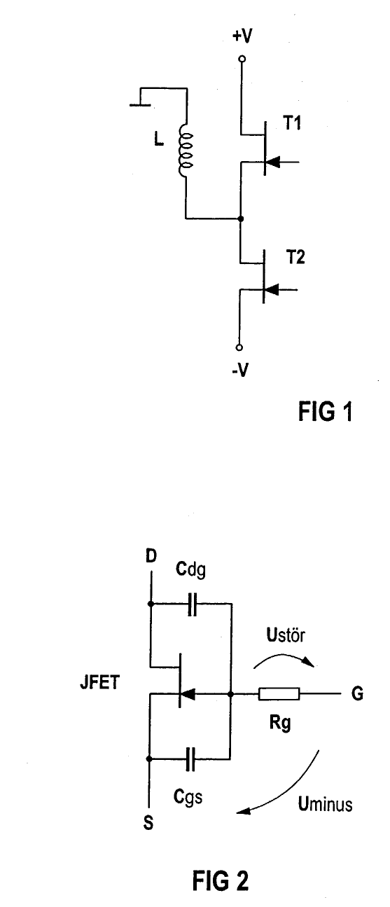

### DETAILED DESCRIPTION OF PREFERRED EMBODIMENTS

Throughout all the Figures, same or corresponding elements are generally indicated by same reference numerals. These depicted embodiments are to be understood as illustrative of the invention and not as limiting in any way.

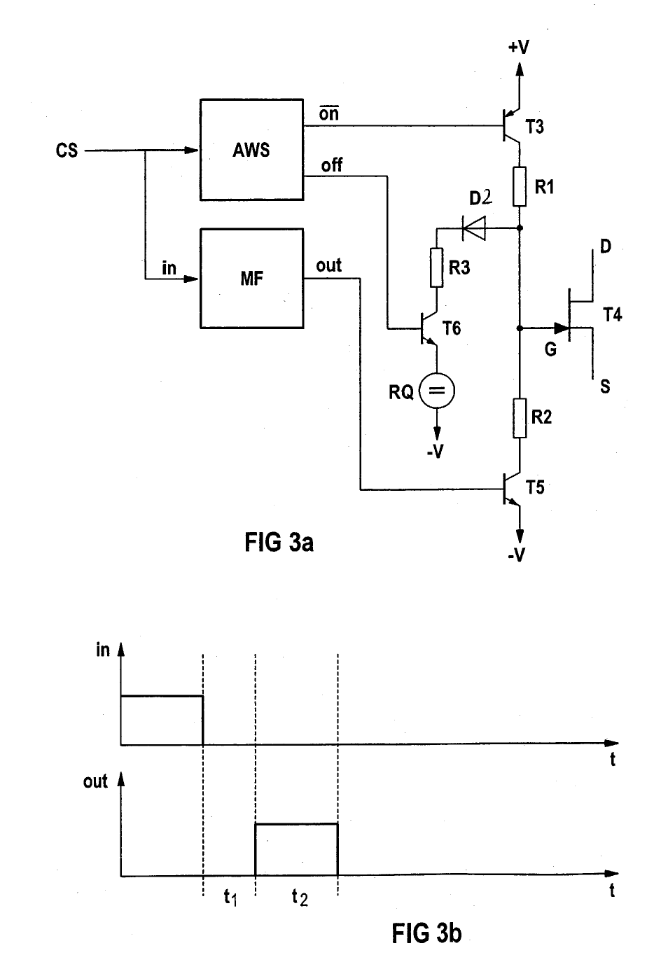

Turning now to the drawing, and in particular to FIG. 3a, there is shown a circuit diagram of a first embodiment of a drive control circuit according to the present invention. A switching signal CS is supplied to an evaluation circuit AWS which produces two complementary control signals ON and OFF with different situation levels. The switching signal CS is further supplied to a monostable multivibrator MF, which outputs a time-delayed impulse in response to an incoming impulse. A positive supply voltage +V is hereby connected to the emitter of a bipolar transistor T3 of pnp-type having a basis which is controlled by the ON signal of the evaluation circuit AWS. The collector of the bipolar transistor T3 is connected across a resistor R1 to a junction point which has further connected thereto also the anode of a diode D2, a terminal of a resistor R2 as well as a gate G of a connected silicon-carbide transistor, namely the junction field-effect transistor T4. The other terminal of the resistor R2 is guided to the collector of a bipolar transistor T5 of npn-type, whose emitter is connected to a negative supply potential −V and whose basis is connected to the output of the monostable multivibrator MF.

The cathode of the diode D2 is guided via a resistor R3 to the collector of a bipolar transistor T6 of npn-type whose basis is controlled by the OFF signal of the evaluation circuit AWS and whose emitter is connected via a reference voltage supply RQ to the negative provisional voltage −V.

The “normal” desired value is applied upon switch-off to the gate G of the junction field-effect transistor T4 by means of the reference voltage supply RQ in conjunction with the bipolar transistor T6, the resistor R3 and the diode D2. In addition, however, the voltage is applied by means of the bipolar transistor T5 for a period defined by the monostable multivibrator MF to the negative supply voltage −V.

FIG. 3b shows a graphical illustration of the pattern of the input signal IN and the output signal OUT of the monostable multivibrator MF. In response to the negative edge of an input impulse, an impulse with the duration t2 is produced after a dead time t1 and thus is time-delayed.

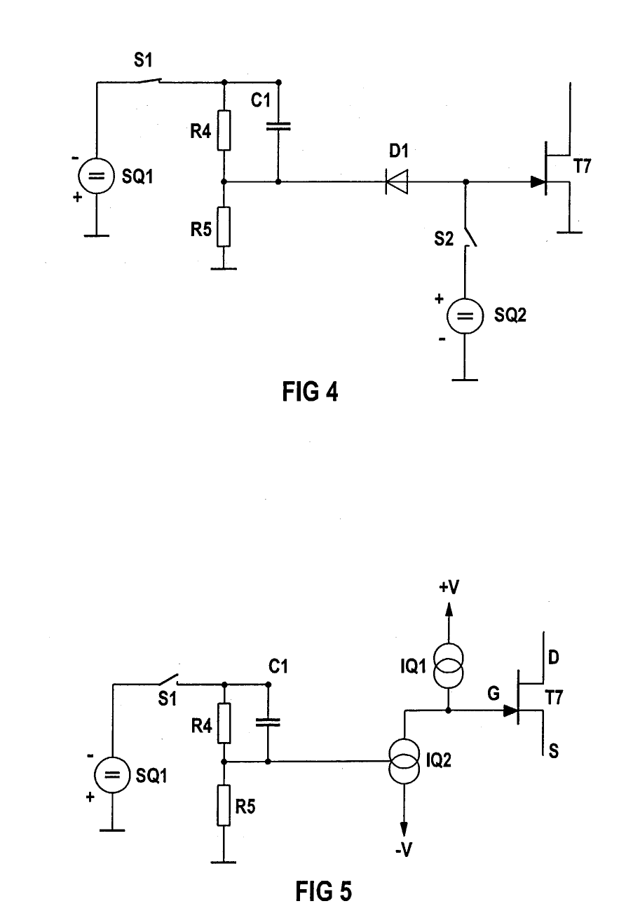

FIG. 4 shows a circuit diagram of another embodiment of a drive control circuit according to the invention for a silicon-carbide junction field-effect transistor T7. In the present exemplified embodiment, the junction field-effect transistor T7 is of the n-channel type and is thus pinched off by a negative voltage and is normally conducting. In the exemplified embodiment, a slightly positive voltage is applied in the conduction state to ensure safe conduction. The gate G is hereby connected to a terminal of a switch S2 whose other terminal is connected to the positive pole of a voltage supply SQ2. Further connected to the gate G is the anode of a diode D1 whose cathode leads to the pick-up of a voltage divider comprised of two resistors R4 and R5. The resistor R5 is grounded while a negative voltage, generated by a voltage supply SQ1, is applied to the pick-up via the resistor R4 as well as via a switch S1, which is operated inversely to the switch S2. A capacitor C1 is connected in parallel to the resistor R4. Although mechanical switches S1 and S2 are shown, controlled switches are in fact involved here, e.g. transistors.

With the switch S1 opened, a positive voltage is established at the gate G of the transistor T7 by the voltage supply SQ2. When the switch S1 is now closed, the voltage on the gate G of the junction field-effect transistor T7 is charged by the voltage supply SQ1 to a negative value, whereby the switch S2 is open. The diode D1 now becomes conducting and charges the gate G of the junction field-effect transistor T7 to approximately the pick-up voltage of the voltage divider. Through the capacitor C1, which is parallel to the resistor R4, the voltage divider changes its divisor relationship over time in such a way that the full voltage of the voltage supply SQ1 is applied at the pick-up voltage, while after a certain time the pick-up voltage is given by the divisor relationship of the resistors R4 and R5. If the resistors R4 and R5 are selected small enough and the capacitance large enough in relation to the developing parasitic capacitances and resistances, then the time behavior is determined to a large extent by the resistors R4 and R5 as well as the capacitor C1. The capacitor C1 initially works like a short-circuit that bridges the resistor R4. The capacitor C1 charges over time, so that the importance of the resistance R4 is increased in relation to the capacitance C1. In this way, a high voltage arrives initially at the gate G of the junction field-effect transistor T7, when the switch S1 is switched on, and then drops to the voltage level given by resistances R4 and R5. The resistor R4 also causes the capacitor C1 to discharge quickly after the switch S1 is opened.

FIG. 5 shows another exemplified embodiment of a drive control circuit according to the invention, which differs from the embodiment of FIG. 4 by substituting the diode D1, the switch S2, and the voltage supply SQ2, with two current supplies IQ1 and IQ2, whereby the current supply IQ2 is voltage-regulated. The current supply IQ1 is hereby connected between the positive supply potential +V and the gate G of the junction field-effect transistor T7, while the current supply IQ2 is connected between the gate G of the junction field-effect transistor T7 and the negative supply potential −V. The voltage for controlling the current supply IQ2 is tapped at the pick-up of the voltage divider with the resistors R4 and R5.

With switch S1 opened, a positive current, which maintains the junction field-effect transistor T7 conducting, is made available by the current supply IQ1. When the switch S1 is now closed, the current supply IQ2 is activated which delivers a larger current than the current supply IQ1. On one hand, this compensates the current of the current supply IQ1 and, on the other hand, pinches off the junction field-effect transistor T7 with the excess (negative) current. As already described in the exemplified embodiment of FIG. 4, the voltage divider (resistors R4 and R5) in connection with the capacitor C1 produces initially a higher voltage, when the switch S1 is switched on, which voltage then drops to a steady-state value. In like manner, the current supply IQ2, controlled by this voltage, produces initially a higher current which then drops to a steady-state value.

While the invention has been illustrated and described in connection with currently preferred embodiments shown and described in detail, it is not intended to be limited to the details shown since various modifications and structural changes may be made without departing in any way from the spirit of the present invention. The embodiments were chosen and described in order to best explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and their equivalents:

What is claimed is:

1. A drive control circuit for a junction field-effect transistor having a gate terminal, a drain terminal and a source terminal, said drive control circuit comprising a controllable current supply or voltage supply to produce a reverse control current or reverse control voltage for the gate, said current supply or voltage supply being controlled in such a way that upon a switch-off of the junction field-effect transistor, the absolute magnitude of the reverse control current or the reverse control voltage assumes initially a higher value and then a lower value, whereby the lower value is sufficient for blocking the junction field-effect of the transistor.

2. The drive control circuit of claim 1, and further comprising a timing control for the current supply or voltage supply for increasing the reverse control current or the reverse control voltage from the lower value to the higher value for a predetermined period of time, when the presence of an edge of a switching signal initiates a switch-off of the junction field-effect of the transistor.

3. The drive control circuit of claim 1, wherein the upper value of the reverse control current or the reverse control voltage is equal to a permissible maximum value for the gate current or gate voltage.

4. The drive control circuit of claim 1, wherein the junction field-effect transistor is a silicon-carbide field-effect transistor.
